(19) United States
(12) Patent Application Publication
(10) Pub. No.: US 2025/0329802 A1
(43) Pub. Date: Oct. 23, 2025

(54) DIGITAL TWIN DEVICE AND DIGITAL TWIN-BASED BATTERY TEMPERATURE MONITORING METHOD

(71) Applicant: KOREA ELECTROTECHNOLOGY RESEARCH INSTITUTE, Changwon-si, Gyeongsangnam-do (KR)

(72) Inventors: Yoon-Cheol HA, Gimhae-si, Gyeongsangnam-do (KR); Chil-Hoon DOH, Changwon-si, Gyeongsangnam-do (KR); Gil Sung BYEON, Changwon-si, Gyeongsangnam-do (KR); Wanbin SON, Yangsan-si, Gyeongsangnam-do (KR); Seung-Wook EOM, Changwon-si, Gyeongsangnam-do (KR); Ji Hyun YU, Yeosu-si, Jeollanam-do (KR); Taijong JUNG, Daejeon (KR)

(21) Appl. No.: 18/263,332

(22) PCT Filed: Jan. 20, 2022
(86) PCT No.: PCT/KR2022/001054

§ 371 Date: Jun. 28, 2024

(30) Foreign Application Priority Data
Feb. 1, 2021 (KR) 10-2021-0013978

(51) Int. Cl. H01M 10/42; G01R 31/367; H01M 10/48

(52) U.S. Cl. CPC H01M 10/425; G01R 31/367; H01M 10/486; H01M 2010/4271

(57) ABSTRACT

The present application relates to a digital twin device and a digital twin-based battery temperature monitoring method. The digital twin-based battery temperature monitoring method, according to one embodiment of the present invention, may comprise the steps of: receiving real-time state information of a battery unit from a battery management system (BMS); carrying out a temperature distribution analysis of the inside of the battery unit by applying the real-time state information to a digital twin corresponding to the battery unit; and transmitting, to the BMS, a virtual temperature value of a virtual point of measurement, which has been requested for by the BMS.

### TECHNICAL FIELD

The disclosure relates to a digital twin device and a digital twin-based battery temperature monitoring method and, more particularly, to a digital twin device and a digital twin-based battery temperature monitoring method capable of providing a temperature change at a major point in a battery unit in real time.

### BACKGROUND ART

A lithium-ion battery applied to an electric vehicle, an energy storage system (ESS), and the like may experience a drastic change in performance depending on the temperature of the battery. That is, when the battery is used at high temperature, aging of the battery may be accelerated, and when the battery is used at low temperature, an available energy range may be reduced, and a problem, such as lithium plating, may occur when a high current is applied.

Conventionally, a method of monitoring the temperature of a battery by directly installing one or more temperature sensors in a battery module is used. However, when a plurality of temperature sensors is installed in a battery unit, a problem may arise due to a defect in the sensors or there is difficulty in designing a hardware layout for connecting the plurality of temperature sensors. Further, in a case of direct measurement with a temperature sensor, it is impossible to measure the internal temperature of each battery in which a temperature change occurs most, and there is a limitation in position and number for measurement.

That is, it is difficult to accurately measure temperature distribution of each battery cell or module, and accordingly preventive measures against aging of the battery unit or a fire accident are ineffective.

### DISCLOSURE OF INVENTION

### Technical Problem

The disclosure is to provide a digital twin device and a digital twin-based battery temperature monitoring method that are capable of preventing rapid aging or an accident due to an excessive increase in temperature in a battery unit.

The disclosure is to provide a digital twin device and a digital twin-based battery temperature monitoring method that are capable of monitoring internal temperature distribution of a battery unit in real time by configuring a digital twin corresponding to the battery unit.

### Solution to Problem

A digital twin-based battery temperature monitoring method according to an embodiment of the disclosure may include: receiving real-time state information about a battery unit from a battery management system (BMS); analyzing internal temperature distribution of the battery unit by applying the real-time state information to a digital twin corresponding to the battery unit; and transmitting, to the BMS, a virtual temperature value at a virtual measurement point requested by the BMS.

The digital twin may be generated by reflecting an electrochemical-thermal model corresponding to the battery unit, an arrangement of cell modules provided in the battery unit, and a heat dissipation structure.

The real-time state information may include at least one of an output current, a charging voltage, a measurement temperature value at a measurement point in the battery unit, a state of charge (SOC), and a state of health (SOH).

The digital twin may be generated by applying the electrochemical-thermal model of any one of an equivalent circuit model (ECM), a Newman-Tiedemann-Gu-Kim (NTGK) model, and a Newman pseudo 2-dimensional (Newman P2D) model.

The digital twin may be generated by machine learning of sample data representing 2D or 3D temperature distribution of the battery unit 20 generated using the NTGK model, and the sample data may be a 2D or 3D image visually representing the 2D or 3D temperature distribution of the battery unit 20.

The digital twin may be generated by machine learning using a neural network including a convolutional neural network (CNN) layer as a hidden layer, and an output layer of the neural network may include an exponential function as an activation function.

According to an embodiment of the disclosure, there may be a computer program stored in a medium that is coupled with hardware to perform the digital twin-based battery temperature monitoring method.

A digital twin device according to an embodiment of the disclosure may include: a receiving unit to receive real-time state information about a battery unit from a battery management system (BMS); a digital twin unit to analyze internal temperature distribution of the battery unit by applying the real-time state information to a digital twin corresponding to the battery unit; and a transmitting unit to transmit, to the BMS, a virtual temperature value at a virtual measurement point requested by the BMS.

The foregoing solutions do not illustrate all features of the disclosure. Various features of the disclosure and advantages and effects thereof may be understood in more detail with reference to the following specific embodiments.

### Advantageous Effects of Invention

A digital twin device and a digital twin-based battery temperature monitoring method according to an embodiment of the disclosure use a digital twin corresponding to a battery unit, and may thus estimate and provide the internal temperature distribution of the battery unit in real time. Further, since the internal temperature distribution in the battery unit may be obtained in real time, it is possible to appropriately take preventive measures against aging of the battery unit and an accident, based on the internal temperature distribution.

According to a digital twin device and a digital twin-based battery temperature monitoring method according to an embodiment of the disclosure, it is possible to estimate temperature at an arbitrary point in a battery unit and to estimate temperature without being limited to a measurement point or the number measurements.

### BRIEF DESCRIPTION OF DRAWINGS

FIG. 1 is a schematic diagram illustrating a power system according to an embodiment of the disclosure;

FIG. 2 is a block diagram illustrating a digital twin device according to an embodiment of the disclosure;

FIG. 3 illustrates electrochemical-thermal modeling of a battery according to an embodiment of the disclosure;

FIG. 4 illustrates comparison between temperature distribution according to prediction of heat generation of a battery by a digital twin device according to an embodiment of the disclosure and temperature distribution obtained through actual measurement with an infrared camera;

FIG. 5 is a block diagram illustrating a digital twin device according to another embodiment of the disclosure; and

FIG. 6 is a flowchart illustrating a battery temperature monitoring method using a digital twin according to an embodiment of the disclosure.

### BEST MODE FOR CARRYING OUT THE INVENTION

Hereinafter, exemplary embodiments will be described in detail with reference to the accompanying drawings so that those skilled in the art to which the present disclosure belongs may easily implement the technical idea of the present disclosure. When detailed descriptions about related known functions or components are determined to make the gist of the disclosure unclear in describing exemplary embodiments of the disclosure, the detailed descriptions will be omitted herein. Like reference numerals are used for parts having similar functions and actions throughout the drawings.

In this specification, it should be understood that when a part is referred to as being “connected” to another part, the part may be connected directly to the other part or may be connected indirectly to the other part with any other part interposed therebetween. The expression that a part “includes” an element means that the part does not exclude another element but may further include another element unless specified otherwise. The terms “unit”, “module”, and the like used herein indicate a unit for processing at least one function or operation, which may be configured as hardware, software, or a combination of hardware and software.

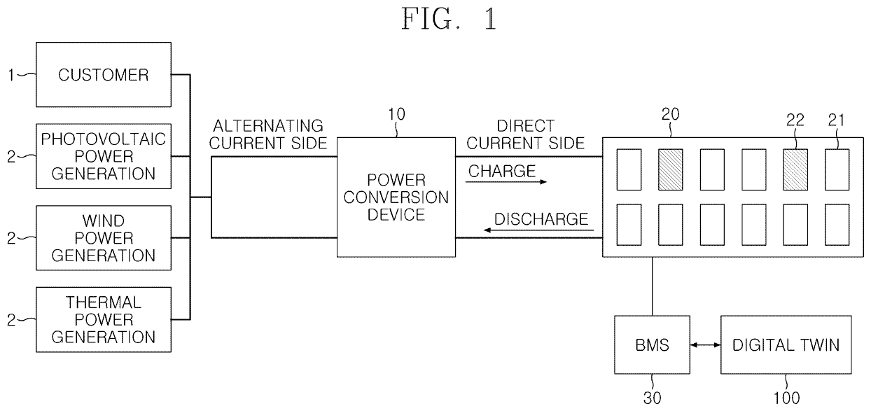

FIG. 1 is a schematic diagram illustrating a power system according to an embodiment of the disclosure.

Referring to FIG. 1, the power system according to the embodiment of the disclosure may include a customer 1, a power generator 2, a power conversion device 10, a battery unit 20, a battery management system (BMS) 30, and a digital twin device 100.

Hereinafter, the power system according to the embodiment of the disclosure will be described with reference to FIG. 1.

The customer 1 may be a house, a factory, a commercial facility, or the like and may consume produced power, and the power generator 2 may produce power, based on various energy sources, such as thermal power, nuclear power, hydropower, wind power, and solar heat. Here, for renewable energy, a component of the battery unit 20 may be further included to stably supply power to a power system.

That is, the battery unit 20 functions to charge and store surplus power produced by the power source 2 and to discharge the charged power to provide the same to the customer 1 when output of the power source 2 is insufficient. However, different types of power may be used such that the customer 1 and the power generator 2 use AC power and the battery unit 20 uses DC power, and rated voltages or rated currents may also have different levels.

Therefore, the power conversion device 10 may be included to convert power types, voltage levels, and the like between the customer 1, the power generator 20, and the battery unit 20. According to an embodiment, the power conversion device 10 may include a power modulation system (PMS), an insulated-gate bipolar transistor (IGBT), and the like, and may perform conversion between a DC and an AC and step up or step down a voltage by using these components.

The battery unit 20 may include electrochemical secondary batteries 21, such as a lithium secondary battery, and the secondary batteries 21 may be provided in a module, pack, rack, or the like in the battery unit 20. Each of the secondary batteries 21 in the battery unit 20 may be charged with charging power received from the power conversion device 10 to store the same.

The battery unit 20 may further include a cooling unit 22, and the cooling unit 22 may further include a heat sink plate or an air conditioner. The air conditioner may include a cooling passage for flow of a cooling medium, and may function to cool the secondary batteries 21 in the battery unit 20 by circulating a cooling medium, such as cooling water, cooling oil, and cooling gas, through an inlet and an outlet of the cooling passage.

According to an embodiment, a temperature sensor may be provided in a set measurement point in the battery unit 20, and an operation of the cooling unit 22 may be controlled such that a temperature value measured at each measurement point does not exceed a set temperature. Here, control of the cooling means 22 may be performed by the BMS 30 or the like.

The BMS 30 is a system that manages the battery units 20. According to an embodiment, the BMS 30 may function to monitor a state of the battery unit 20, to maintain an optimal condition for an operation of the battery units 20, and to predict a battery replacement time. In addition, the BMS 30 may detect a problem occurring in the battery unit 20, and may generate a control or command signal related to the battery unit 20 to control the state or operation of the battery unit 20.

The state of the battery unit 20 may include a state related to an amount of charge and lifespan of each of the secondary batteries 21, and may include a state of charge (SOC) and a state of health (SOH). The SOC quantitatively represents the amount of charge of the secondary batteries 21, and may be used to identify how much energy is stored in the secondary batteries 21. According to an embodiment, the amount of SOC may be expressed as percentage (%) ranging from 0 to 100%. For example, 0% may denote a fully discharged state, and 100% may denote a fully charged state. This expression form may be variously modified and defined according to an intention of design or an embodiment. The SOH quantitatively represents a change in lifespan characteristic of the secondary batteries 21 due to aging, and denotes how much the secondary batteries 21 have been degraded in lifespan or capacity. The BMS 30 may generate an SOC and SOH of the battery unit 20 or each of the secondary batteries 21 included in the battery unit 20, and may use various techniques to generate the SOC and SOH of the battery unit 20.

Since the BMS 30 is able to control the operation of the battery unit 20, the BMS 30 may function to charge the secondary batteries 21 in the battery unit 20 with charging power when the charging power is applied from the power generator 2, and to discharge power charged in the battery unit 2 to supply the power to the customer 1 when the output of the power generator 2 is insufficient. In addition, the BMS 30 may perform an operation of balancing the secondary batteries 21 in the battery unit 20, or may function to control an operation of the cooling unit 22 to maintain a constant temperature in the battery unit 20.

Generally, in a case of the electrochemical secondary batteries 21, such as the lithium secondary battery, temperature changes of a cell and a module may occur depending on characteristics of heat generation (ohmic heating, irreversible reaction heat, reversible reaction heat, and the like) due to charging and discharging and a heat dissipation structure (conduction, convection, radiant cooling, and the like). A safe temperature range may be set according to the type of a material used for the secondary batteries 21, and rapid aging or an accident may occur when the temperature is out of the range. According to an embodiment, the BMS 30 may further include a separate control module to indirectly or directly control the temperature in the battery unit 20.

Conventionally, the temperature is measured at a plurality of measurement points located on the surface of each secondary battery cell or module such that the BMS 30 may control the temperature in the battery unit 20. However, in actual measurement using the temperature sensor, since the temperature sensor is attached to the surface of the secondary batteries 21, it is impossible to measure the internal temperature of each secondary battery cell in which a temperature change occurs most, and there is a limitation in position and number for measurement. That is, it is difficult to accurately monitor temperature distribution of each cell or module of the secondary batteries 21, and accordingly preventive measures against aging of the secondary batteries 21 in the battery unit 20 or a fire accident are ineffective.

However, the power system according to the embodiment of the disclosure further includes the digital twin device 100, and may accurately monitor the internal temperature of the cell or module of the secondary batteries 21 by using the digital twin device 100. That is, a digital twin is a virtual model identically representing a physical object, and the digital twin device 100 may generate a digital twin of the battery unit 20 to provide a simulation result of internal temperature distribution of the battery unit 20.

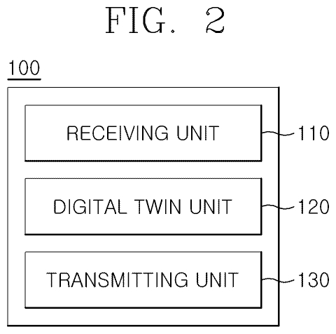

Since the digital twin is generated by identically modeling the battery unit 20 installed in the actual power system, a temperature distribution result obtained by the digital twin device 100 from the digital twin may be virtually the same as that of the actual battery unit 20. Therefore, using the digital twin makes it possible to obtain accurate internal temperature distribution of the actual battery unit 20, and makes it possible to derive the internal temperature distribution of the battery unit 21 in real time when conditions actually applied to the battery unit 21 are input in real time. That is, using the digital twin device 100 makes it possible to easily obtain the temperature distribution of the secondary batteries 21, and the BMS 20 may control operating conditions for the battery unit 20 by using the temperature distribution of the secondary batteries 21 to prevent a battery accident and to extend the lifespan of the batteries. Hereinafter, a digital twin device 100 according to an embodiment of the disclosure will be described with reference to FIG. 2.

FIG. 2 is a block diagram illustrating a digital twin device 100 according to an embodiment of the disclosure. Referring to FIG. 2, the digital twin device 100 according to the embodiment of the disclosure may include a receiving unit 110, a digital twin unit 120, and a transmitting unit 130.

The receiving unit 110 may receive real-time state information about a battery unit 20 from a BMS 30. That is, the BMS 30 may collect the real-time state information from the battery unit 20, and may then provide the real-time state information to the receiving unit 110 so that the digital twin device 100 reflects the real-time state information about each battery unit 20.

The real-time state information may include an output current and a charging voltage of the battery unit 20, a measurement temperature value measured at each measurement point provided in the battery unit 20, a state of charge (SOC), and a state of health (SOH).

The battery unit 20 may include a plurality of measurement sensors, and the BMS 30 may receive measurement values from the respective measurement sensors. The measurement sensor may include a current sensor, a voltage sensor, a temperature sensor, and the like. The BMS 30 may calculate an SOC or SOH of the battery unit 20 by using the measurement values. Subsequently, the BMS 30 may transmit the received measurement values and the calculated SOC and SOH as real-time state information to the receiving unit 110, and the receiving unit 110 may provide the received real-time state information to the digital twin unit 120. The receiving unit 110 may support wired or wireless communication for communication with the BMS 30.

The digital twin unit 120 may interpret internal temperature distribution of the battery unit 20 by applying the real-time state information to a digital twin. That is, the digital twin unit 120 may generate the digital twin that operates identically to the battery unit 20 by modeling the battery unit 20. To this end, the digital twin unit 120 may reflect an electrochemical-thermal model corresponding to the battery unit 20, an arrangement of secondary batteries 21 provided in the battery unit 20, a heat dissipation structure of a cooling unit, and the like in the digital twin. The electrochemical-thermal model applicable to the digital twin may include an equivalent circuit model (ECM), a Newman-Tiedemann-Gu-Kim (NTGK) model, a Newman pseudo 2-dimensional (Newman P2D) model, and the like.

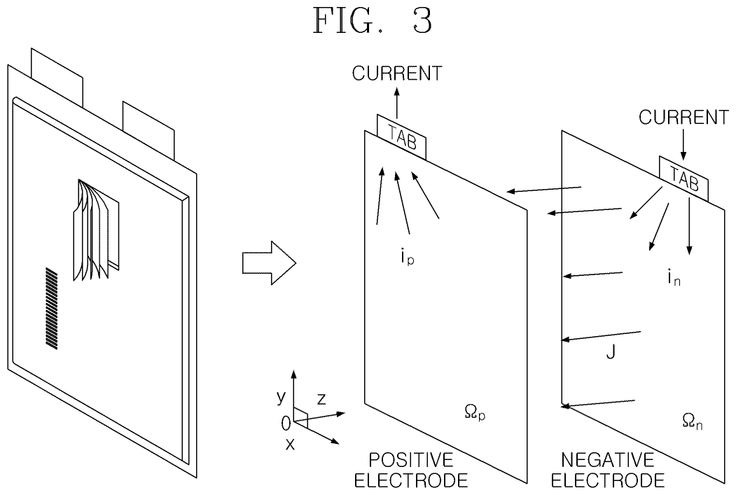

Referring to FIG. 3, the digital twin unit 120 may generate the digital twin by applying a semi-empirical two-dimensional model, such as the NTGK model, to interpret the internal temperature distribution of the battery unit 20 according to the inputted real-time state information.

Generally, the equivalent circuit model has difficulty in predicting physical changes occurring inside a cell while having simplicity and a fast operation, and an electrochemical model may predict various physical phenomena while having a slow operation, making it difficult to commercially use the equivalent circuit model and the electrochemical model. However, the Newman-Tiedemann-Gu-Kim (NTGK) model is a semi-empirical two-dimensional electrochemical-thermal model based on test data about a secondary battery cell, and may be conveniently applied to predict performance, heat generation, and aging.

Therefore, when a digital twin is generated using the NTGK model, it is possible to analyze characteristics of the secondary batteries 21, such as local heat generation by position, through analysis of charge/discharge behavior of the secondary batteries 21 and current density distribution and potential distribution of electrodes (positive electrodes and negative electrodes) of the secondary batteries 21.

Specifically, the digital twin unit 120 may generate the digital twin by applying basic parameter information about the secondary batteries 21, where a basic parameter may include information obtained from a geometric structure and constituent materials of the secondary batteries 21, such as density (ρ), specific heat (Cp), thermal conductivity (k), electrode resistance (positive electrode resistance Ωp and negative electrode resistance Ωn), specific surface area (total cell specific surface area a, positive electrode specific surface area ap, and negative electrode specific surface area an), a convective heat transfer coefficient (h), and the like.

Subsequently, the digital twin unit 120 may apply the real-time state information, such as an output current (positive electrode output current ip and negative electrode output current in), received from the receiving unit 110 to the digital twin, thus obtaining temperature distribution of the battery unit 20.

Although obtaining the temperature distribution according to heat generation of the secondary batteries 21 by using the digital twin has been illustrated, it is also possible to perform characteristic analysis on performance or aging of the secondary batteries 21 according to an embodiment.

According to an embodiment, the digital twin unit 120 may also generate a digital twin for the battery unit 20 by using a machine learning technique. That is, the digital twin unit 120 may set an appropriate supervised learning model in consideration of characteristics of the actual battery unit 20 and a driving goal of an operator, and may then configure a digital twin from the supervised learning model through learning.

Specifically, the digital twin unit 120 may first determine a variable of a supervised learning model for performing supervised learning, based on the collected real-time state information. Here, the variable for supervised learning may include an independent variable corresponding to input data and a dependent variable corresponding to output data. For example, the digital twin unit 110 may determine the temperature distribution of the battery unit 20 as a dependent variable and may determine the real-time state information as an independent variable, thereby configuring the supervised learning model to output the temperature distribution of the battery unit 2, based on the real-time state information.

Subsequently, the digital twin unit 120 may perform preprocessing on respective pieces of learning data determined as an independent variable and a dependent variable. For example, the digital twin unit 120 may detect missing data or an outlier of the learning data, and may correct the detected missing data and outlier according to a predetermined preprocessing method.

When the preprocessing is completed, the digital twin unit 120 may perform an operation of classifying the pieces of preprocessed learning data into a training data set and a test data set. The training data set may be used to generate a digital twin, and the test data set may be used to verify the generated digital twin.

The digital twin unit 120 may perform a predetermined supervised learning algorithm, based on the training data set. As the supervised learning algorithm, a robust regression algorithm or a neural network algorithm may be used. However, the supervised learning algorithm is not limited to the above algorithms, and any algorithm capable of performing supervised learning may be used.

The digital twin unit 120 may train the supervised learning algorithm by repeatedly applying the supervised learning algorithm to the supervised learning model until prediction accuracy of the dependent variable in the supervised learning algorithm exceeds a reference value. When the prediction accuracy of the dependent variable reaches the reference value or higher, the supervised learning model may determine that a digital twin simulating an operation of the actual battery unit 20 is generated. Subsequently, the digital twin unit 120 may verify performance of the generated digital twin, based on the test data set.

According to an embodiment, it is also possible to generate sample data for machine learning of a digital twin by using the NTGK model. That is, sample data representing 2D or 3D temperature distribution of the battery unit 20 according to various inputs may be generated in advance using the NTGK model. For example, a battery discharge rate (c-rate) and an external temperature may be input to the NTGK model, thereby outputting the temperature of the battery unit 20 to be divided in a 27*35 grid. Here, the NTGK model may be applied in parallel to a plurality of CPUs, thereby quickly generating sample data.

Temperature distribution of the battery unit 20 may be expressed by dividing the battery unit 20 in a 2D or 3D grid and indicating temperature at each point. According to an embodiment, the temperature distribution of the battery unit 20 may be visualized to generate a 2D or 3D image.

The temperature distribution of the battery unit 20 may have locality. That is, since temperature at a specific point in the battery unit 20 is closely related to temperature at a different neighboring point, it is possible to more accurately and efficiently generate a digital twin by using the locality of the temperature distribution of the battery unit 20. In addition to the temperature distribution, distributions, such as current density distribution and potential distribution, may also have similar locality.

Accordingly, the digital twin unit 120 may utilize a convolutional neural network (CNN) that utilizes locality to derive the temperature distribution in the battery unit 20. That is, using an element of a neural network for image processing, such as the convolutional neural network, as a hidden layer makes it possible to establish an efficient learning model for the temperature distribution in the battery unit 20. According to an embodiment, a recurrent neural network, such as a fully connected (FC) layer, a long-short term memory (LSTM), or a gated recurrent unit (GRU), may also be used as the hidden layer of the learning model.

For example, the neural network of the learning model may be configured in an input layer-fully connected layer-convolutional neural network layer-maximum pooling layer-convolutional neural network layer-maximum pooling layer-fully connected layer-output layer structure. Here, since the temperature of the battery unit 20 tends to increase explosively from a specific threshold value, using a nonlinear function, such as an exponential function, as an activation function of the last output layer makes it possible to generate a more accurate digital twin model.

In addition, the trained neural network may be stored as a separate file, and may be invoked to be used when necessary. Accordingly, it is possible to avoid repeatedly performing learning that takes great time. Further, the trained neural network may be used as an initial value of the neural network for learning of a different type of battery or learning according to different input and output conditions, thus inducing faster learning. That is, effective application to other systems or batteries may be implemented through transfer learning.

When the digital twin is generated, the digital twin unit 120 may predict the temperature distribution of the battery unit 20 corresponding to a response variable from the real-time state information corresponding to an observation variable by using the digital twin.

The transmitting unit 130 may transmit, to the BMS 30, a virtual temperature value at a virtual measurement point requested by the BMS 30. Here, the transmitting unit 130 may be provided with the internal temperature distribution of the entire battery unit 20 from the digital twin unit 120, and may thus provide all virtual temperature values at arbitrary virtual measurement points requested by the BMS 30. According to an embodiment, an influential point within each battery cell included in the battery unit 20 may be set in advance, and a virtual temperature value may be generated by designating the point as a virtual measurement point. Subsequently, the BMS 30 may reflect the received virtual temperature value at each virtual measurement point to adjust operating conditions for preventing an accident of the batteries and extending the lifespan of the batteries.

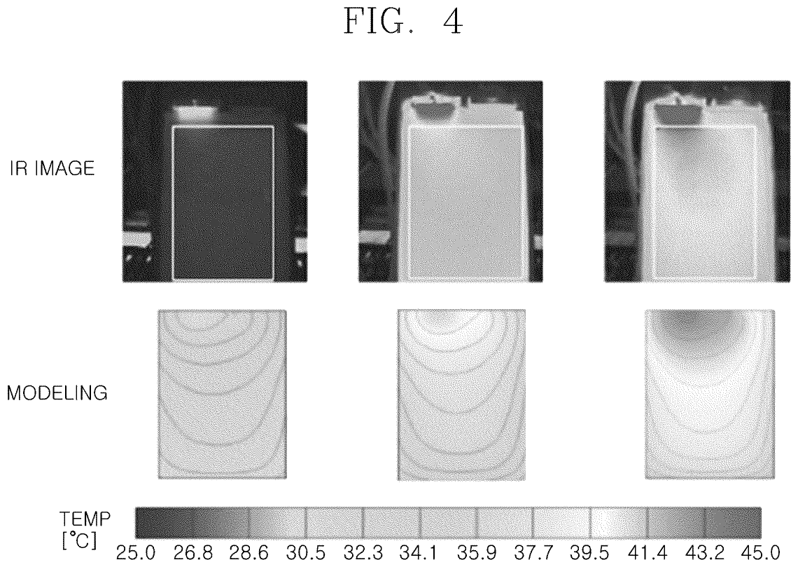

FIG. 4 illustrates comparison between internal temperature distribution (modeling) of the battery unit 20 obtained by the digital twin device 100 and internal temperature distribution (IR image) of the battery unit 20 obtained through actual measurement with an infrared camera. It is identified that the temperature distribution actually measured using the infrared camera is generated similarly to the virtual temperature distribution generated by the digital twin device 100. That is, as illustrated in FIG. 4, when the digital twin device 100 inputs real-time state information about the battery unit 20 to the digital twin, 2D or 3D internal temperature distribution of the battery unit 20 may be generated.

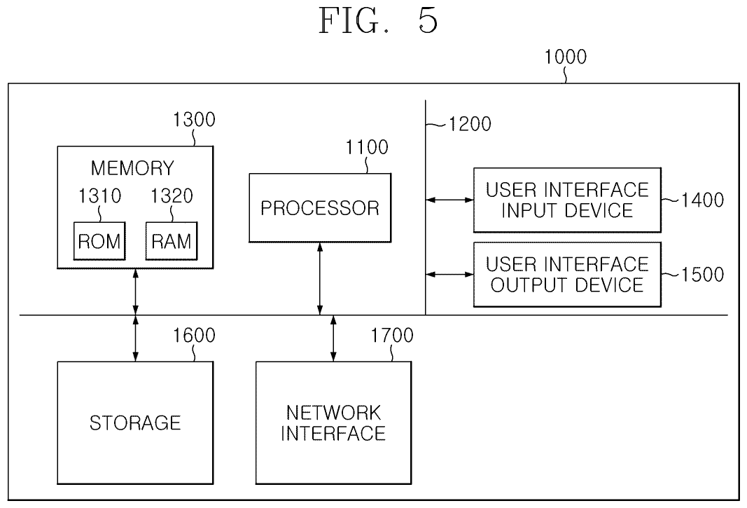

FIG. 5 illustrates a digital twin device according to another embodiment of the disclosure. The digital twin device according to the other embodiment of the disclosure may be configured as hardware, software, or a combination thereof. For example, the digital twin device of the disclosure may be configured as a computing system 1000 having at least one processor to perform the foregoing functions/operations/processes as shown in FIG. 5 or as a server on the Internet.

The computing system 1000 may include the at least one processor 1100, a memory 1300, a user interface input device 1400, a user interface output device 1500, a storage 1600, and a network interface 1700 that are connected through a bus 1200. The processor 1100 may be a central processing unit (CPU) or a semiconductor device that processes instructions stored in the memory 1300 and/or the storage 1600. The memory 1300 and the storage 1600 may include various types of volatile or nonvolatile storage media. For example, the memory 1300 may include a read-only memory (ROM) 1310 and a random access memory (RAM) 1320.

Accordingly, operations of methods or algorithms described in connection with embodiments disclosed herein may be directly configured as hardware, a software module, or a combination of the hardware and the software module executable by the processor 1100. The software module may reside in a computer-readable storage/recording medium (i.e., the memory 1300 and/or the storage 1600), such as a RAM memory, a flash memory, a ROM memory, an EPROM memory, an EEPROM memory, a register, a hard disk, a removable disk, and a CD-ROM. The illustrative storage medium may be coupled to the processor 1100, and the processor 1100 may read information from the storage medium and may write information in the storage medium. Alternatively, the storage medium may be integrated with the processor 1100. The processor and the storage medium may reside in an application-specific integrated circuit (ASIC). The ASIC may reside in a user terminal. Alternatively, the processor and the storage medium may reside as separate components in a user terminal.

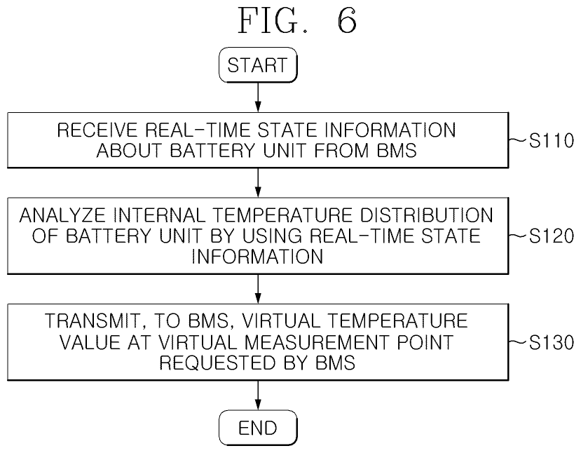

FIG. 6 is a flowchart illustrating a digital twin-based battery temperature monitoring method according to an embodiment of the disclosure. Each operation may be performed by a digital twin device.

First, referring to FIG. 6, the digital twin device may receive real-time state information about a battery unit from a BMS (S110). That is, the BMS may collect the real-time state information from the battery unit, and may then provide the real-time state information to the digital twin device so that the digital twin device may reflect the real-time state information about each battery unit.

The real-time state information may include an output current and a charging voltage of the battery unit, a measurement temperature value measured at each measurement point provided in the battery unit, a state of charge (SOC), and a state of health (SOH).

The battery unit may include a plurality of measurement sensors, and the BMS 30 may receive measurement values from the respective measurement sensors. The measurement sensor may include a current sensor, a voltage sensor, a temperature sensor, and the like. The BMS may calculate an SOC or SOH of the battery unit by using the measurement values. Subsequently, the BMS may transmit the received measurement values and the calculated SOC and SOH as real-time state information to the digital twin device.

The digital twin device may interpret internal temperature distribution of the battery unit by applying the real-time state information to a digital twin corresponding to the battery unit (S120). That is, the digital twin device may generate the digital twin that operates identically to the battery unit by modeling the battery device. To this end, the digital twin device may generate the digital twin by applying an electrochemical-thermal model corresponding to the battery unit and by reflecting an arrangement of secondary batteries provided in the battery unit and a heat dissipation structure of a cooling unit. The electrochemical-thermal model applied to the digital twin may include an ECM, a Newman-Tiedemann-Gu-Kim (NTGK) model, a Newman P2D model, and the like.

According to an embodiment, it is possible to generate sample data for machine learning of the digital twin by using the NTGK model. That is, sample data representing 2D or 3D temperature distribution of the battery unit according to various inputs may be generated in advance using the NTGK model. The sample data may represent temperature at each point by dividing the battery unit in a 2D or 3D grid. According to an embodiment, the sample data may be a 2D or 3D image obtained by visualizing the temperature distribution.

Since the temperature distribution of the battery unit has locality, the digital twin may be trained using a convolutional neural network that utilizes locality. That is, using an element of a neural network for image processing, such as the convolutional neural network, as a hidden layer makes it possible to establish an efficient learning model for the temperature distribution in the battery unit. According to an embodiment, a recurrent neural network, such as a fully connected layer, an LSTM, or a GRU, may also be used as the hidden layer of the learning model.

For example, the neural network of the learning model may be configured in an input layer-fully connected layer-convolutional neural network layer-maximum pooling layer-convolutional neural network layer-maximum pooling layer-fully connected layer-output layer structure. Here, since the temperature of the battery unit tends to increase explosively from a specific threshold value, using a nonlinear function, such as an exponential function, as an activation function of the last output layer makes it possible to generate a more accurate digital twin model.

Subsequently, the digital twin device may analyze heat generation characteristics of the battery unit by using the digital twin, and may derive 2D or 3D temperature distribution of the battery unit through the characteristics.

Specifically, the digital twin device may apply basic parameter information about the secondary batteries to the digital twin, where the basic parameter information may include information obtained from a geometric structure and constituent materials of the secondary batteries, such as density, specific heat, thermal conductivity, electrode resistance, specific surface area, a convective heat transfer coefficient, and the like. The digital twin device may obtain the 2D or 3D temperature distribution of the battery unit by further applying the received real-time state information, such as an output current.

The digital twin device may transmit, to the BMS, a virtual temperature value at a virtual measurement point requested by the BMS (S130). The digital twin device generates temperature distribution in the entire area inside the battery unit, and may thus provide all virtual temperature values at arbitrary virtual measurement points requested by the BMS. According to an embodiment, among points included in the battery unit, a point having the highest influence due to heat generation may be set in advance, and may be designated as a virtual measurement point. Subsequently, the BMS may reflect the received virtual temperature value at each virtual measurement point to adjust operating conditions for preventing an accident of the batteries and extending the lifespan of the batteries.

The disclosure is not limited to the foregoing embodiments and the appended drawings. It will be obvious to those skilled in the art to which the disclosure pertains that a component according to the disclosure can be substituted, modified, or changed within the spirit of the disclosure.

1. A digital twin-based battery temperature monitoring method comprising:
receiving real-time state information about a battery unit from a battery management system (BMS);
analyzing internal temperature distribution of the battery unit by applying the real-time state information to a digital twin corresponding to the battery unit; and
transmitting, to the BMS, a virtual temperature value at a virtual measurement point requested by the BMS.

2. The digital twin-based battery temperature monitoring method of claim 1, wherein the digital twin is generated by reflecting an electrochemical-thermal model corresponding to the battery unit, an arrangement of cell modules provided in the battery unit, and a heat dissipation structure.

3. The digital twin-based battery temperature monitoring method of claim 1, wherein the real-time state information comprises at least one of an output current, a charging voltage, a measurement temperature value at a measurement point in the battery unit, a state of charge (SOC), and a state of health (SOH).

4. The digital twin-based battery temperature monitoring method of claim 2, wherein the digital twin is generated by applying the electrochemical-thermal model of any one of an equivalent circuit model (ECM), a Newman-Tiedemann-Gu-Kim (NTGK) model, and a Newman pseudo 2-dimensional (Newman P2D) model.

5. The digital twin-based battery temperature monitoring method of claim 4, wherein the digital twin is generated by machine learning of sample data representing 2D or 3D temperature distribution of the battery unit (20) generated using the NTGK model, and
the sample data is a 2D or 3D image visually representing the 2D or 3D temperature distribution of the battery unit (20).

6. The digital twin-based battery temperature monitoring method of claim 5, wherein the digital twin is generated by machine learning using a neural network comprising a convolutional neural network (CNN) layer as a hidden layer, and
an output layer of the neural network comprises an exponential function as an activation function.

7. A computer program stored in a medium that is coupled with hardware to perform the digital twin-based battery temperature monitoring method of any one of claims 1 to 6.

8. A digital twin device comprising:
a receiving unit configured to receive real-time state information about a battery unit from a battery management system (BMS);
a digital twin unit configured to analyze internal temperature distribution of the battery unit by applying the real-time state information to a digital twin corresponding to the battery unit; and
a transmitting unit configured to transmit, to the BMS, a virtual temperature value at a virtual measurement point requested by the BMS.
